(19) United States
(12) Patent Application Publication
(10) Pub. No.: US 2010/0218823 A1
(43) Pub. Date: Sep. 2, 2010

(54) ELECTRODE SUBSTRATE FOR PHOTOELECTRIC CONVERSION ELEMENT, METHOD OF MANUFACTURING ELECTRODE SUBSTRATE FOR PHOTOELECTRIC CONVERSION ELEMENT, AND PHOTOELECTRIC CONVERSION ELEMENT

(75) Inventors: Hiroshi Matsui, Sakura-shi (JP); Kenichi Okada, Sakura-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIKURA LTD., Tokyo (JP)

(21) Appl. No.: 12/780,570

(22) Filed: May 14, 2010

Related U.S. Application Data
(63) Continuation of application No. PCT/JP2008/070757, filed on Nov. 14, 2008.

(30) Foreign Application Priority Data
Nov. 15, 2007 (JP) 2007-296440

(51) Int. Cl. H01L 31/0296; H01L 31/18; H01L 31/0224

(52) U.S. Cl. 136/256; 438/85; 257/E31.126; 257/E31.015

(57) ABSTRACT

A method of manufacturing an electrode substrate for a photoelectric conversion element which includes: forming a transparent conductive layer and a collector wire on a substrate; forming an oxide semiconductor layer in a region of the transparent conductive layer different from a region in which the collector wire is formed; forming an porous oxide semiconductor layer by firing the oxide semiconductor layer; after firing, forming a protective layer covering the collector wires, the protective layer composed of an insulating resin having a thermal resistance at 250° C. or higher; heating the substrate at 250° C. or higher during or after the formation of the protective layer; and after the heating, allowing adsorption of dyes in the porous oxide semiconductor layer.

Priority is claimed from Japanese Patent Application No. 2007-296440, filed on Nov. 15, 2007, the contents of which is incorporated herein by reference.

### BACKGROUND OF THE INVENTION

1. Field of the Invention

Exemplary embodiments of the present invention related to an electrode substrate used for a photoelectric conversion element such as a dye-sensitized solar cell and the like, a method of manufacturing an electrode substrate for a photoelectric conversion element, and a photoelectric conversion element.

2. Description of the Related Art

For an electrode substrate used for a photoelectric conversion element such as a dye-sensitized solar cell, a transparent conductive layer formed on a surface of a transparent substrate has been used. When a large-area and high-output element (module) for practical use is to be manufactured, there have been attempts such as forming collector wires to increase conductivity of the electrode substrate in order to suppress increase in internal resistance caused by low conductivity of the transparent conductive substrate. For the collector wires, a material with a high conductivity and a particularly, low resistance such as metal (for example, silver, copper, and the like) may be used. In addition, as an electrolyte (for example, an iodine electrolyte) used for the element, a chemically and electrochemically (practically) inactive electrolyte may be used. Therefore, applying an insulating layer or a transparent conductive layer to the metal wiring layer as a protective layer has been proposed (see Published Japanese Translation No. 2000-536805 of PCT International Publication, Japanese Unexamined Patent Application, First Publication No. 2004-220920, Japanese Unexamined Patent Application, First Publication No. 2004-146425, PCT International Publication No. WO2004/032274, Japanese Unexamined Patent Application, First Publication No. 2007-042366, and M. Spath, et al., Progress in Photovoltaics: Research and Applications, vol. 11, pp. 207-220, 1115 (2003)).

For the collector wires, a dense protective layer without defectiveness is needed to completely block the metal wires and the iodine electrolyte. As the wire protective layer, an inorganic material such as a transparent conductive metal oxide layer, glass, and the like have been considered. However, forming a dense layer composed of the inorganic material so as not to allow the electrolyte to permeate is difficult. In addition, since the inorganic material is hard and brittle, thermal expansion and the like should be controlled.

In addition, for the wire protective layer, a resin material has also been considered. However, the resin material generally has low thermal resistance, and high-temperature firing cannot be performed on oxide semiconductor nanoparticles included in an optical electrode of a dye-sensitized solar cell. Particularly, when a cured resin is used, volatile components from the cured resin may contaminate nanoparticle surfaces, and this affects the electricity generation performance.

In addition, when a transparent conductive metal oxide is used as the protective layer in a method of forming a wire protective layer, a large facility such as a vacuum apparatus (used for sputtering, deposition, and the like), a CVD apparatus, or the like is needed. In addition, a technique using a thermoplastic resin film has been considered. However, there is a problem with positional accuracy when a wiring pattern is complex such that film bonding is difficult.

### SUMMARY OF THE INVENTION

Exemplary embodiments are designed to solve the above-mentioned problems. An object of exemplary embodiments is to provide an electrode substrate used for a photoelectric conversion element, a method of manufacturing an electrode substrate for a photoelectric conversion element, and a photoelectric conversion element, with which a dense protective layer without defectiveness can be formed and electricity generation performance can be enhanced.

Exemplary embodiments provide a method of manufacturing an electrode substrate for a photoelectric conversion element which includes: forming a transparent conductive layer on a substrate; forming a collector wire on the substrate; forming an oxide semiconductor layer on the transparent conductive layer in a region different from a regions in which the collector wire is formed; firing the oxide semiconductor layer and forming a porous oxide semiconductor layer; after the firing, forming a protective layer covering the collector wire, the protective layer composed of an insulating resin having a thermal resistance at 250° C. or higher; heating the substrate at approximately 250° C. or higher during or after the formation of the protective layer; and after heating the substrate, allowing adsorption of dyes in the porous oxide semiconductor layer.

A heating temperature at which the substrate is heated may be lower than a firing temperature at which the porous oxide semiconductor layer is fired.

Exemplary embodiments also provide an electrode substrate device for a photoelectric conversion element which includes: a substrate; a transparent conductive layer disposed on the substrate; a collector wire disposed on the substrate; a porous oxide semiconductor layer disposed on the transparent conductive layer in a region different from a region in which the collector wire is formed; and a protective layer covering the collector wire, the protective layer composed of an insulating resin having a thermal resistance at 250° C. or higher.

The insulating resin may be one or more resins selected from a group consisting of a polyimide derivative, a silicone compound, a fluorine elastomer, and a fluorine resin.

Exemplary embodiments also provide a photoelectric conversion element including the above-mentioned electrode substrate device and a counter electrode.

In an exemplary method of manufacturing the electrode substrate for a photoelectric conversion element, before forming the wire protective layer composed of the insulating resin, the oxide semiconductor layer can be sufficiently fired and the porous oxide semiconductor layer can be formed. In addition, since the insulating resin is used for the protective layer, a dense protective layer without defectiveness can be formed. In addition, after forming the protective layer, the heating process may be performed thereon before dye adsorption. Therefore, the method can be used for manufacturing a photoelectric conversion element having high electricity generation characteristics.

In the electrode substrate for a photoelectric conversion element according to exemplary embodiments, the protective layer has thermal resistance at 250° C. or higher. Therefore, after forming the porous oxide semiconductor layer by firing the oxide semiconductor layer, the heating process is performed thereon before dye adsorption, so that contaminants adsorbed in the porous oxide semiconductor layer can be reduced.

### BRIEF DESCRIPTION OF THE DRAWINGS

FIG. 1 is a sectional view illustrating a first example of an electrode substrate for a photoelectric conversion element.

FIG. 2 is a sectional view illustrating a second example of the electrode substrate for a photoelectric conversion element.

FIG. 3A is a process view illustrating a cross-section, which is for explaining a method of manufacturing the electrode substrate for a photoelectric conversion element illustrated in FIG. 1.

FIG. 3B is a process view illustrating a cross-section, which is for explaining the method of manufacturing the electrode substrate for a photoelectric conversion element illustrated in FIG. 1.

FIG. 3C is a process view illustrating a cross-section, which is for explaining the method of manufacturing the electrode substrate for a photoelectric conversion element illustrated in FIG. 1.

FIG. 3D is a process view illustrating a cross-section, which is for explaining the method of manufacturing the electrode substrate for a photoelectric conversion element illustrated in FIG. 1.

FIG. 4A is a process view illustrating a cross-section, which is for explaining a method of manufacturing the electrode substrate for a photoelectric conversion element illustrated in FIG. 2.

FIG. 4B is a process view illustrating a cross-section, which is for explaining the method of manufacturing the electrode substrate for a photoelectric conversion element illustrated in FIG. 2.

FIG. 4C is a process view illustrating a cross-section, which is for explaining the method of manufacturing the electrode substrate for a photoelectric conversion element illustrated in FIG. 2.

FIG. 4D is a process view illustrating a cross-section, which is for explaining the method of manufacturing the electrode substrate for a photoelectric conversion element illustrated in FIG. 2.

FIG. 5 is a sectional view illustrating a third example of the electrode substrate for a photoelectric conversion element a.

FIG. 6 is a sectional view illustrating a fourth example of the electrode substrate for a photoelectric conversion element a.

FIG. 7 is a sectional view illustrating an example of a photoelectric conversion element.

### DETAILED DESCRIPTION OF THE INVENTION

Hereinafter, exemplary embodiments will be described with reference to the accompanying drawings.

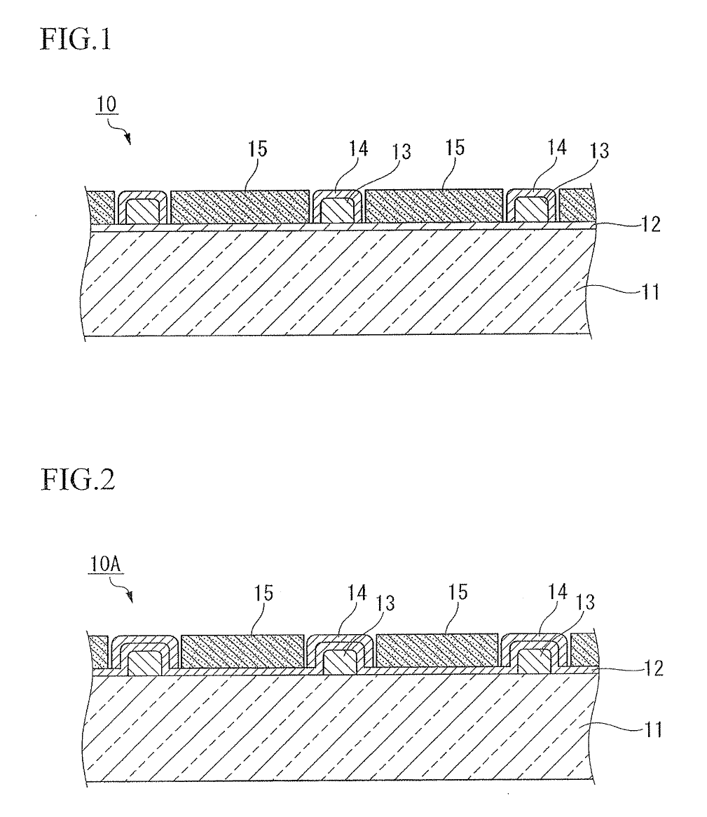

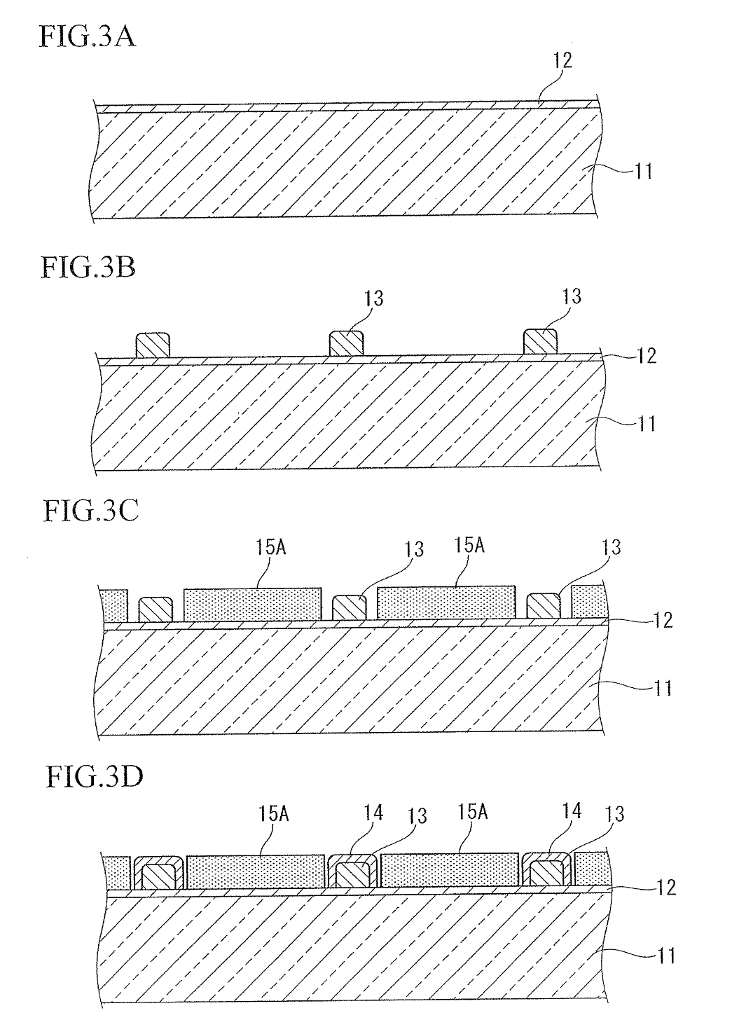

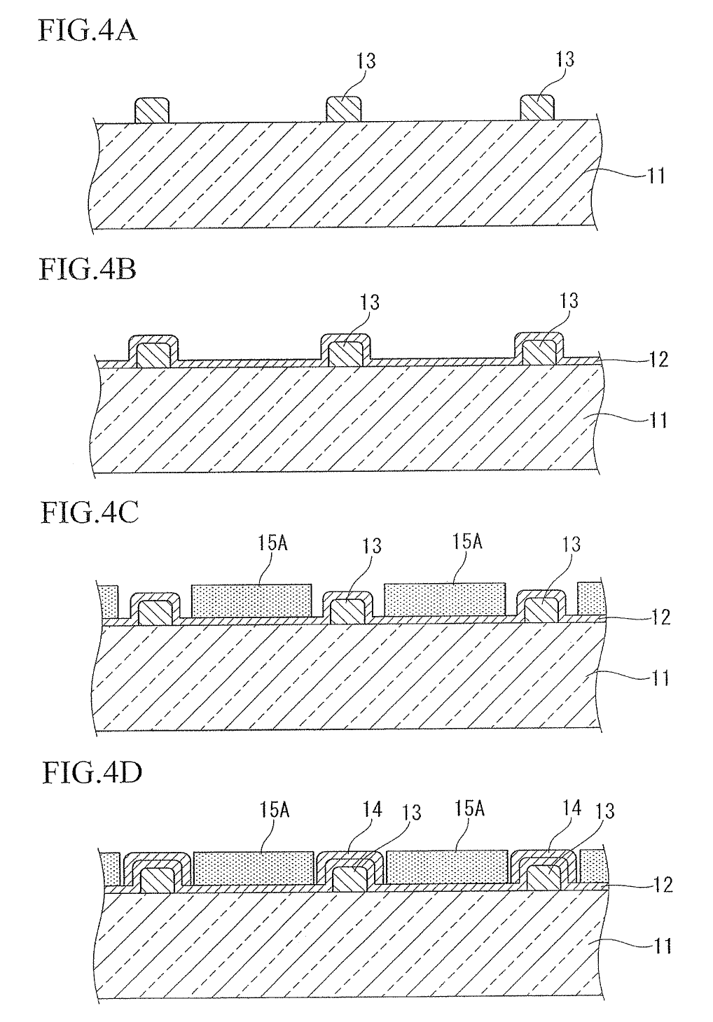

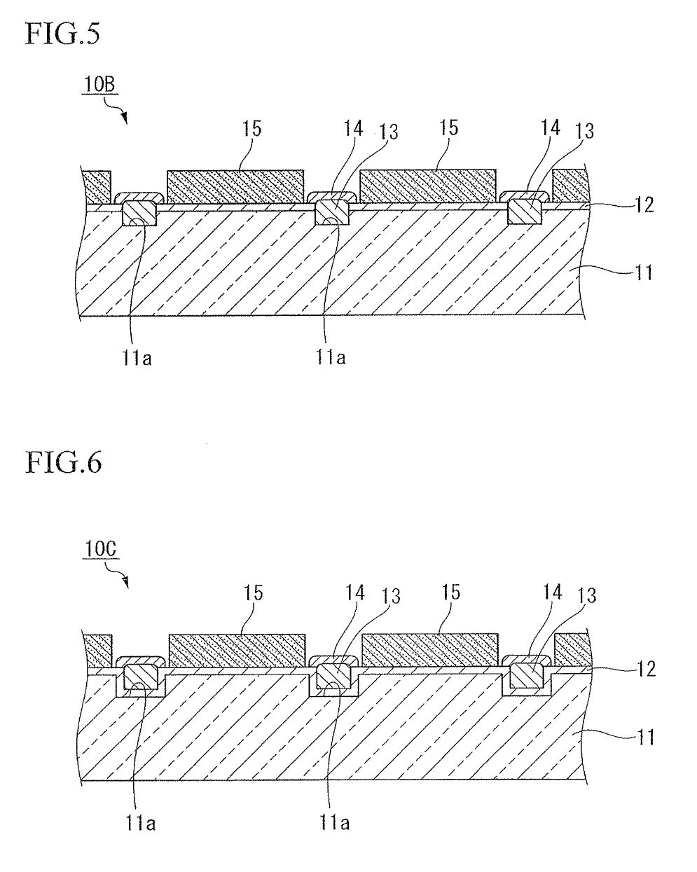

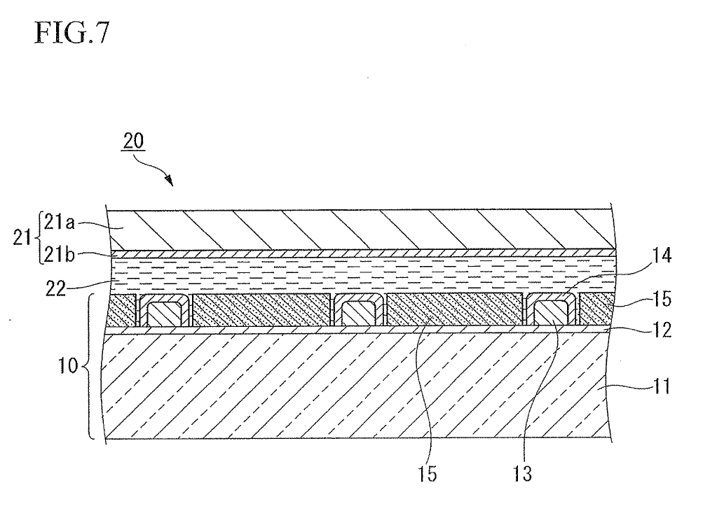

FIG. 1 is a sectional view illustrating a first example of an electrode substrate for a photoelectric conversion element. FIG. 2 is a sectional view illustrating a second example of the electrode substrate for a photoelectric conversion element. FIGS. 3A to 3D are process views illustrating cross-sections, which are for explaining a method of manufacturing the electrode substrate for the photoelectric conversion element illustrated in FIG. 1. FIG. 4A to 4D are process views illustrating cross-sections, which are for explaining a method of manufacturing the electrode substrate for the photoelectric conversion element illustrated in FIG. 2. FIG. 5 is a sectional view illustrating a third example of the electrode substrate for a photoelectric conversion element. FIG. 6 is a sectional view illustrating a fourth example of the electrode substrate for a photoelectric conversion element. FIG. 7 is a sectional view illustrating an example of a photoelectric conversion element.

The electrode substrate 10 for a photoelectric conversion element illustrated in FIG. 1 includes a substrate 11, a transparent conductive layer 12 formed on the substrate 11, collector wires 13 formed on the transparent conductive layer 12, a protective layer 14 composed of an insulating resin formed to cover the collector wires 13, and a porous oxide semiconductor layer 15 formed on different portions of the transparent conductive layer 12 from portions thereof on which the collector wires 13 are formed. A number of the collector wires 13 may be one or more.

The electrode substrate 10A for a photoelectric conversion element illustrated in FIG. 2 includes a substrate 11, collector wires 13 formed on the substrate 11, a transparent conductive layer 12 formed on portions of the substrate 11 where the collector wires 13 are not formed and on the collector wires 13, a protective layer 14 composed of an insulating resin formed to cover the collector wires 13 with the transparent conductive layer 12 interposed therebetween, and a porous oxide semiconductor layer 15 provided on different portions of the transparent conductive layer 12 from portions thereof on which the collector wires 13 are formed.

As a material of the substrate 11, any material providing a transparent substrate, such as glass, resin, ceramic, and the like, may be used without limitation. Particularly, so as not to cause deformation, transformation, or the like of the substrate upon forming of the porous oxide semiconductor layer by firing the oxide semiconductor layer, a high-strain-point glass may be used for its excellent thermal resistance. However, soda-lime glass, white glass, borosilicate glass, or the like may be suitably used.

A material of the transparent conductive layer 12 is not limited. For example, a conductive metal oxide such as tin-doped indium oxide (ITO), tin oxide (SnO₂), fluorine-doped tin oxide (FTO), or the like may be employed. As a method of forming the transparent conductive layer 12, a method suitable for a corresponding material may be used. For example, sputtering, deposition, spray pyrolysis deposition (SPD), chemical vapor deposition (CVD), or the like may be used. In addition, in consideration of light transparency and conductivity, the thickness of the transparent conductive layer 12 may be in the range of 0.001 to 10 μm.

The collector wire or wires 13 may be composed of metal such as gold, silver, copper, platinum, aluminum, nickel, titanium, or the like and formed in a pattern such as a grid pattern, a striped pattern, a comb pattern, or the like. So as not to significantly affect light transparency of the electrode substrate, the width of each wire may be not greater than 1,000 μm. The thickness (height) of each of the wires constituting the collector wires 13 is not particularly limited and may be in the range of 0.1 to 20 μm.

As a method of forming the collector wires 13, for example, there is a method in which a metal powder that serves as conductive particles is mixed with a binder such as glass fine particles into a paste form, the paste is applied to form a predetermined pattern by a printing technique such as screen printing, dispensing, metal mask printing, inkjet printing, or the like, and the conductive particles are fused by firing. The firing temperature may be 600° C. or less, or may be 550° C. or less, when the substrate 11 is, for example, a glass substrate. In addition, forming methods such as sputtering, deposition, plating, or the like may be used. In terms of conductivity, the volume resistivity of the collector wires 13 may be less than or equal to 10⁻⁵ Ω·cm.

The protective layer 14 is composed of an insulating resin having thermal resistance at 250° C. or higher so as to be able to be subjected to heat treatments at 250° C. or higher. Particularly, an insulating resin having thermal resistance at 300° C. or higher may be used.

When the outer appearance of a resin is not deformed and weight reduction thereof is less than or equal to 30% during exposure for 1 to 2 hours at the set temperature, the temperature is determined as the thermal resistance temperature of the resin. Therefore, an insulating resin having thermal resistance at 250° C. or higher means an insulating resin of which weight reduction during exposure at a temperature of 250° C. for 1 to 2 hours is less than or equal to 30%, and an insulating resin having thermal resistance at 300° C. or higher means an insulating resin of which weight reduction during exposure at a temperature of 300° C. for 1 to 2 hours is less than or equal to 30%.

As an insulating resin having thermal resistance at 250° C. or higher, at least one selected from a polyimide derivative, a silicone compound, a fluorine elastomer, and a fluorine resin may used singly or in combination by blending or lamination. The fluorine resin may selected from the group consisting of compounds such as polytetrafluoroethylene, a tetrafluoroethylene-perfluoroalkylvinylether copolymer, a tetrafluoroethylene-hexafluoropropylene copolymer, and the like (for example, Teflon, registered trademark). In addition, as an insulating resin having thermal resistance at 300° C. or higher, one or more kinds of those insulating resins having a thermal resistance at 300° C. or higher among insulating resins having thermal resistance at 250° C. or higher may be selected for use. By applying a resin material having a high flexibility to the insulating resin layer, concerns about impact failure, fracture, and the like of the protective layer 14 decrease.

As a method of forming the protective layer 14, there is a method of applying a varnish or a paste including the insulating resin. In order to enhance a density of the protective layer 14, the application may be repeatedly performed to form a multilayer.

The porous oxide semiconductor layer 15 is a porous layer obtained by firing oxide semiconductor nanoparticles (fine particles with an average particle diameter of 1 to 1,000 nm). As the oxide semiconductor, one or more kinds selected from the group consisting of titanium oxide (TiO₂), tin oxide (SnO₂), tungsten oxide (WO₃), zinc oxide (ZnO), niobium oxide (Nb₂O₅), or the like may be used. The thickness of the porous oxide semiconductor layer 15 may range, for example, from 0.5 to 50 μm.

As a method of forming the porous oxide semiconductor layer 15, for example, a method may be employed, in which a desired additive is added to a dispersion liquid in which commercially available oxide semiconductor fine particles are dispersed in a dispersion medium, or to a colloid solution that can be adjusted by a sol-gel process, depending on applications, and the liquid is applied by a method such as screen printing, inkjet printing, roll coating, doctor blade coating, spin coating, spray coating, or the like. Alternately, an electrophoretic deposition may be employed for depositing oxide semiconductor fine particles immersed in a colloid liquid by electrophoresis. Alternately, a method of mixing a blowing agent with a colloid liquid or a dispersion liquid and applying and firing the mixture so as to be porous may be employed. Finally, a method of adding polymer microbeads so as to be mixed and applied and removing the polymer microbeads to form pores by performing heat treatment or chemical treatment, or the like may be employed.

Sensitizing dyes to be carried on the porous oxide semiconductor layer 15 are not limited and may be suitably selected from a ruthenium complex or an iron complex with a ligand including a bipyridine structure, a ter-pyridine structure, or the like, a metal complex based on porphyrin or phthalocyanine, an organic dye or the like as derivative such as eosin, rhodamine, coumarin, merocyanine, or the like, depending on applications and the material of the oxide semiconductor porous layer.

The electrode substrate for a photoelectric conversion element in this embodiment may be manufactured with the following operations.

The transparent conductive layer 12 and the collector wires 13 are formed on the substrate 11. In this process, the temporal relationship between the formation of the transparent conductive layer 12 and the formation of the collector wires 13 is not limited, and either of forming the collector wires 13 after forming the transparent conductive layer 12, or forming the transparent conductive layer 12 after forming the collector wires 13, is acceptable. In addition, as illustrated in FIG. 1, when the collector wires 13 and the porous oxide semiconductor layer 15 are to be provided on the transparent conductive layer 12, forming the porous oxide semiconductor layer 15 may be performed before forming the collector wires 13.

For example, as illustrated in FIG. 1, when the electrode substrate 10 in which the collector wires 13 are provided on the transparent conductive layer 12 is to be manufactured, a method of forming the collector wires 13 on the transparent conductive layer 12, as illustrated in FIG. 3B, after forming the transparent conductive layer 12 on the substrate 11, as illustrated in FIG. 3A, may be employed.

In addition, as illustrated in FIG. 2, when the electrode substrate 10A in which the transparent conductive layer 12 is provided on the collector wires 13 is to be manufactured, a method of forming the transparent conductive layer 12 on the collector wires 13, as illustrated in FIG. 4B, after forming the collector wires 13 on the substrate 11, as illustrated in FIG. 4A, may be employed.

As described above, after forming the substrate 11 having the transparent conductive layer 12 and the collector wires 13 thereon, as illustrated in FIG. 3C, or forming the collector wires 13 and subsequently forming the conductive layer, as illustrated in FIG. 4C, the oxide semiconductor layer is formed by a method of applying a paste of oxide semiconductor nanoparticles to different portions of the transparent conductive layer 12 from portions thereof on which the collector wires 13 are formed. After forming the oxide semiconductor layer, the oxide semiconductor layer is fired at a temperature of about 400 to 550° C. and the porous oxide semiconductor layer 15A is formed.

After firing the porous oxide semiconductor layer 15A, as illustrated in FIGS. 3D and 4D, the protective layer 14, composed of the insulating resin, is formed to cover the collector wires 13. During or after the process of forming the protective layer 14 and before a process of allowing the adsorption of dyes in the porous oxide semiconductor layer 15A, a process of heating the substrate 11 is additionally provided. The heating temperature in the heating process may be lower than the firing temperature in the firing process.

The heating process may be performed after the process of forming the protective layer 14. Specifically, when the insulating resin used for forming the protective layer 14 is, for example, a thermosetting resin and needs to be heated during the curing reaction, the heating process may be performed during the process of forming the protective layer 14. Otherwise, the heating process may be performed during and after the process of forming the protective layer 14.

The heating temperature in the heating process is 250° C. or higher. By performing heat treatment at a temperature of 250° C. or higher, the organic materials (contaminants) adsorbed on the surface of the porous oxide semiconductor layer 15A can be removed, and the contaminants are prevented from inhibiting the dyes from being carried (adsorption of dyes in the porous oxide semiconductor layer 15A). The heating temperature in the heating process may be 300° C. or higher.

After forming the protective layer 14, by allowing adsorption of the dyes in the porous oxide semiconductor layer 15A, as illustrated in FIGS. 1 and 2, the electrode substrates 10 and 10A having the porous oxide semiconductor layers 15 in which the dyes are adsorbed are completed. A method of forming the protective layer composed of the insulating resin after the process of allowing adsorption of the dyes may be considered. However, in consideration of the contamination on the surface of the collector wires 13 and damage to the dyes during curing (heat treatment in case of a thermosetting resin, UV irradiation in case of a UV curing resin, and the like) of the insulating resin, allowing the dyes to be carried after forming the protective layer 14 may be preferable.

For the electrode substrates, the substrate 11 may be the substrate 11 of which the surface is flat as illustrated in FIGS. 1 and 2. Otherwise, as illustrated in FIGS. 5 and 6, by using a substrate 11 having concave portions 11a as grooves aligned with the collector wires 13 on the surface, at least a lower portion or the entire portion of the collector wire 13 may be formed inside the concave portion 11a. The electrode substrates may be manufactured by the same manufacturing method of the electrode substrates illustrated in FIGS. 1 and 2 except that the collector wires 13 are formed along the concave portions 11a.

For example, an electrode substrate 10B illustrated in FIG. 5, includes a substrate 11 having concave portions 11a, a transparent conductive layer 12 formed on different portions of the substrate 11 from portions at which the concave portions 11a are formed, collector wires 13 formed from the bottom of the concave portions 11a, a protective layer 14 composed of an insulating resin and formed to cover the collector wires 13, and a porous oxide semiconductor layer 15 formed on different portions of the transparent conductive layer 12 from portions thereof on which the collector wires 13 are formed.

In addition, an electrode substrate 10C illustrated in FIG. 6, includes a substrate 11 having concave portions 11a, a transparent conductive layer 12 formed on the substrate 11 and lower and side surfaces of the concave portions 11a, collector wires 13 formed on the transparent conductive layer 12 inside the concave portions 11a, a protective layer 14 composed of an insulating resin and formed to cover the collector wires 13, and a porous oxide semiconductor layer 15 provided on different portions of the transparent conductive layer 12 from portions thereof on which the collector wires 13 are formed.

An electrode substrate for a photoelectric conversion element according to exemplary embodiments may be used as an optical electrode of a photoelectric conversion element such as a dye-sensitized solar cell. FIG. 7 illustrates a configuration example of the photoelectric conversion element 20 (a dye-sensitized solar cell). The dye-sensitized solar cell includes an optical electrode including the electrode substrate 10 for a photoelectric conversion element of the embodiment, a counter electrode 21 facing the optical electrode, and an electrolyte 22 filled between the electrodes. In FIG. 7, the electrode substrate 10 for a photoelectric conversion element illustrated in FIG. 1 is exemplified. However, any one of the electrode substrates 10A, 10B, and 10C for a photoelectric conversion element illustrated in FIGS. 2, 5, and 6, respectively, or any electrode substrate for a photoelectric conversion element as described herein can be used.

As the counter electrode 21, although not particularly limited, specifically those in which a catalyst layer 21b such as platinum, carbon, a conductive polymer, and the like is formed on a surface of a base material 21a such as a metal plate, a metal foil, and a glass plate may be used. In order to enhance conductivity of the surface of the counter electrode, an additional conductive layer may be provided between the base material 21a and the catalyst layer 21b.

As the electrolyte 22, an organic solvent including a redox pair, a room-temperature molten salt (ionic liquid), or the like may be used. In addition, instead of an electrolyte liquid, an electrolyte solution may be used, which is added with a suitable gellant (for example, a high-molecular gellant, a low-molecular gellant, various types of nanoparticles, carbon nanotubes, or the like) and may be quasi-solidified so as to become what is known as a gel electrolyte.

As the organic solvent, although not particularly limited, one or more kinds of acetonitrile, methoxyacetonitril, propionitril, methoxypropionitril, propylene carbonate, diethyl carbonate, γ-butyrolactone, or the like may be used. As the room-temperature molten salt, one or more kinds of room-temperature molten salt including a cation such as an imidazolium cation, a pyrrolidinium cation, a pyridinium cation, or the like and an anion such as an iodide ion, a bis[(trifluoromethyl)sulfonyl]amide anion, a dicyanoamide anion, a thiocyanic acid anion, or the like may be used.

As the redox pair contained in the electrolyte, although not particularly limited, one or more kinds of pairs such as an iodine/iodide ion, a bromine/bromide ion, or the like may be added. As a source of the iodide ion and the bromide ion, one or more selected from lithium salt, quaternary imidazolium salt, tetrabutylammonium salt, or the like, which contain the anion of the iodine ion or the bromide ion, may be used singly, or in combination. To the electrolyte, as needed, an additive such as 4-tert-butylpyridine, N-methylbenzimidazol, guadinium salt, or the like may be added.

In a photoelectric conversion element according described exemplary embodiments, the collector wires of the electrode substrate are provided with the protective layer without defects such as pinholes, so that the photoelectric conversion element can achieve excellent electricity generation performance.

### EXAMPLES

Now, Examples the described embodiments will be described in detail. In addition, the invention is not limited to the examples.

### Manufacturing of Electrode Substrate

### Glass Substrate

i) high-strain-point glass PD200 (Asahi glass Co. Ltd)

ii) heat-resistant glass TEMPAX 8330 (SCHOTT)

iii) commercially available FTO glass (Nihon sheet glass Co. Ltd)

### Wire Protective Material

a) polyimide varnish (I. S. T), breaking elongation 5% or higher (about 65%), curing temperature Max 350° C. to 400° C.

b) silicone varnish (of GE Toshiba silicone Co. Ltd), breaking elongation 5% or higher, curing temperature 300° C. or less

c) fluorine elastomer SIFEL (of Shin-Etsu chemical Co. Ltd), breaking elongation 5% or higher (about 200%), curing temperature 300° C. or less

d) polytetrafluoroethylene coating material (of Nippon fine coatings Inc), breaking elongation 5% or higher, treatment temperature 300° C. or less

e) low-melting-point glass (of Fukuda metal foil & powder Co. Ltd), breaking elongation less than 5%, firing temperature 450° C.

f) UV curing resin (of Threebond Co. Ltd)

In addition, in order to examine thermal resistance of the wire protective materials (a) to (d), each material was heated at 250° C. for 1 hour, and weight reduction and the outer appearance thereof were measured. The weight reduction of each material was less than or equal to 30%, and the outer appearance thereof had no problems. Thermal resistance of the wire protective material (d) was also examined as described above. Here, the weight reduction thereof was higher than 30%, and the outer appearance had problems.

Glass substrates (which were 140 mm square and coated with an FTO film on the surface) of (i), (ii), and (iii) were prepared, and a silver circuit was formed on the FTO film in a grid pattern by screen printing. In designing the shape of the circuit, the circuit width was set to 300 μm, and the thickness was set to 10 μm. For printing, silver paste with a volume resistivity after firing of 3×10⁻⁶ Ωcm was used. After printing, the silver paste was dried at 130° C., and the silver circuit was fired at the maximum temperature of 510° C., thereby forming the circuit.

Next, on different portions of the FTO film from portions thereof on which the silver circuit was formed, a paste containing TiO₂ nanoparticles was applied by screen printing, dried, and fired at 500° C., thereby forming the porous oxide semiconductor layer.

Next, the wire protective materials of (a) to (f) were applied to overlap with the circuit formation portion and completely cover the silver circuit, and treated at the maximum temperature of 300 to 350° C., thereby forming the wire protective layer. Here, for those requiring heating only at a temperature lower than 300° C. during the formation of the wire protective layer, heat treatment was performed at 300° C. for 1 hour after the formation of the wire protective layer, so as to remove contaminants on the surface of the porous oxide semiconductor layer. The design width of the wire protective layer was set to 600 μm, and the wire protective layer was applied by screen printing or dispensing while aligned with the silver circuit by using a CCD camera.

For the electrode substrates manufactured as described above, 14 combinations of the glass substrate and the wire protective material were obtained as combinations of (i) and (a), (ii) and (a), (iii) and (a), (i) and (b), (ii) and (b), (iii) and (b), (i) and (c), (ii) and (c), (iii) and (c), (i) and (d), (ii) and (d), (iii) and (d), (i) and (f), and (ii) and (e).

In a comparative example using the combination of (i) and (f), the resin layer was damaged by the heat treatment at 300° C., so that it could not function as the wire protective layer. In a comparative example using the combination of (ii) and (e), the protective layer was observed after the firing process. Here, a crack connected to the silver circuit had occurred, and characteristics to be satisfied for the wire protective layer could not be obtained.

### Examination on Heat Treatment Temperature

In a desiccator, a glass substrate of which a surface was coated with the varnish of (a), and an FTO electrode substrate including a titania (TiO₂) porous layer which is 5 mm square were left for a day. Thereafter, heat treatment was performed thereon at each corresponding treatment temperature represented in left sections of Table 1 for 30 minutes to carry the dyes. By combining the FTO electrode substrate on which the dyes were carried as the optical electrode with the counter electrode and the electrolyte, a small cell was manufactured, and photoelectric conversion characteristics thereof were measured. The measurement results are represented in Table 1.

TABLE 1

| Treatment | Photoelectric |
|---|---|
| Temperature | Conversion Efficiency |
| 100° C. | 3.2% |
| 150° C. | 3.3% |
| 200° C. | 4.6% |
| 250° C. | 5.1% |
| 300° C. | 7.0% |
| 350° C. | 7.2% |
| 400° C. | 7.2% |

From the measurement results, it can be seen that the proper heat treatment temperature for removing contaminants on the surface of the porous oxide semiconductor layer caused by the varnish may be 250° C. or higher, or may be 300° C. or higher.

### Manufacturing of Dye-Sensitized Solar Cell

By using the electrode substrate having the aforementioned construction, a dye-sensitized solar cell was manufactured, and characteristic evaluation thereof was performed. The method of manufacturing the dye-sensitized solar cell and the measurement condition are described as follows.

The glass substrates (which is 140 mm square and coated with an FTO film on the surface) of (i), (ii), and (iii) were prepared, and a silver circuit (with a circuit width of 300 μm and a thickness of 10 μm) was formed on the FTO film by screen printing. Thereafter, a paste including TiO₂ nanoparticles was applied on different portions of the FTO film from portions thereof on which the silver circuit was formed, by screen printing, and then dried and fired at 500° C., thereby forming the porous oxide semiconductor layer. Next, the wire protective materials of (a) to (f) were applied to overlap with the circuit formation portion and completely cover the silver circuit, thereby forming the wire protective layer (with the design width of 600 μm). Here, for those requiring heating only at a temperature lower than 300° C. during the formation of the wire protective layer, heat treatment was performed at 350° C. for 1 hour after the formation of the wire protective layer so as to remove contaminants on the surface of the porous oxide semiconductor layer. This was immersed into an acetonitrile/t-butanol solution of ruthenium bipyridine complex (N719 dye) for more than a day so as to carry the dyes, thereby manufacturing the optical electrode.

As the counter electrode, a titanium (Ti) foil and a platinum (Pt) layer formed thereon by sputtering were used. In a circulation and purification type glove box filled with inert gas, an iodine electrolyte is deployed so as to be stacked on the optical electrode and face the counter electrode, and the periphery of the element is sealed by the UV curing resin. As the iodine electrolyte, the following A and B were used. In addition, M represents mol/L.

Electrolyte A; 0.5M 1,2-dimethyl-3-propylimidazolium iodide and 0.05 M iodine was dissolved in methoxyacetonitril, and an adequate amount of lithium iodide and 4-tert-butylpyridine was added thereto.

Electrolyte B; 1-hexyl-3-methyl imidazolium iodide and iodine were mixed at a molar ratio of 10:1, an adequate amount of N-methylbenzimidazol and thiocyanic acid guadinium was added thereto, and SiO₂, nanoparticles of 4 wt % were mixed therewith, followed by kneading into a quasi-solid.

Electricity generation characteristics of the dye-sensitized solar cell were measured by irradiating quasi-sunlight of AM1.5, 100 mW/cm². The measurement results are represented in Table 2.

TABLE 2

| Electrode Substrate | | Photoelectric Conversion Efficiency | |
|---|---|---|---|
| Substrate | Protective Layer | Electrolyte A | Electrolyte B |
| i) | a) | 5.8% | 4.1% |
| ii) | a) | 5.7% | 3.9% |
| iii) | a) | 6.1% | 3.9% |
| i) | b) | 5.7% | 3.6% |
| ii) | b) | 5.4% | 3.9% |
| iii) | b) | 5.8% | 4.0% |
| i) | c) | 5.6% | 3.7% |
| ii) | c) | 6.1% | 3.7% |
| iii) | c) | 5.5% | 3.6% |
| i) | d) | 5.2% | 3.4% |
| ii) | d) | 5.5% | 3.4% |
| iii) | d) | 5.6% | 3.7% |
| i) | f) | 1.4% | 1.1% |
| ii) | e) | 3.0% | 2.4% |

From the measurement results, it can be seen that in the 12 examples from (i)-(a) to (iii)-(d), both of the electrolytes A and B had obtained good photoelectric conversion efficiency. The combinations in the comparative examples of (i)-(f) and (ii)-(e) showed low photoelectric conversion efficiency.

Described exemplary embodiments can be used for the photoelectric conversion element such as a dye-sensitized solar cell.

Although the above exemplary embodiments of have been described, it will be understood by those skilled in the art that the present invention should not be limited to the described exemplary embodiments, but that various changes and modifications can be made within the spirit and scope of the present invention.

What is claimed is:

1. A method of manufacturing an electrode substrate for a photoelectric conversion element, the method comprising:
forming a transparent conductive layer and a collector wire on a substrate;
forming an oxide semiconductor layer on the transparent conductive layer in a region different from a region in which the collector wire is formed;
forming a porous oxide semiconductor layer by firing the oxide semiconductor layer;
after the firing, forming a protective layer covering the collector wire, wherein the protective layer comprises an insulating resin having a thermal resistance at 250° C. or higher;
heating the substrate at approximately 250° C. or higher during or after the forming of the protective layer; and
after the heating the substrate, allowing adsorption of dyes in the porous oxide semiconductor layer.

2. The method according to claim 1, wherein a heating temperature at which the substrate is heated is lower than a firing temperature at which the porous oxide semiconductor layer is fired.

3. An electrode substrate device for a photoelectric conversion element, comprising:
a substrate;
a transparent conductive layer and a collector wire disposed on the substrate;
a porous oxide semiconductor layer disposed on the transparent conductive layer in a region different from a region in which the collector wire is formed; and
a protective layer covering the collector wire, wherein the protective layer comprises an insulating resin having a thermal resistance at 250° C. or higher.

4. The electrode substrate device according to claim 3, wherein the insulating resin is one or more resins selected from a group consisting of a polyimide derivative, a silicone compound, a fluorine elastomer, and a fluorine resin.

5. A photoelectric conversion element comprising:
an electrode substrate device, comprising:
a substrate;
a transparent conductive layer disposed on the substrate;
a collector wire disposed on the substrate;
a porous oxide semiconductor layer disposed on the transparent conductive layer in a region different from a region in which the collector wire is formed; and
a protective layer covering the collector wire, wherein the protective layer comprises an insulating resin having a thermal resistance at approximately 250° C. or higher; and
a counter electrode.

6. A method of manufacturing an electrode substrate for a photoelectric conversion element, the method comprising:
forming a transparent conductive layer on a substrate;
forming a collector wire on the transparent conductive layer;
forming a porous oxide semiconductor layer on the transparent conductive layer in a region different from a region in which the collector wire is formed;
firing the porous oxide semiconductor layer at a first temperature;
forming a protective layer covering the collector wire, wherein the protective layer comprises an insulating resin having a thermal resistance at a temperature of about 250° C. or higher;
heating the substrate at a second temperature during or after the forming of the protective layer; and
allowing adsorption of dyes in the porous oxide layer.

7. The method according to claim 6, wherein the first temperature is higher than the second temperature.

8. The method according to claim 6, wherein the insulating resin has a thermal resistance at a temperature of about 300° C. or higher.

9. A method of manufacturing an electrode substrate for a photoelectric conversion element, the method comprising:
forming a collector wire on a substrate;
forming a transparent conductive layer on the substrate and over the collector wire;
forming a porous oxide semiconductor layer on the transparent conductive layer in a region different from a region in which the collector wire is formed;
firing the porous oxide semiconductor layer at a first temperature;
forming a protective layer covering the collector wire, wherein the protective layer comprises an insulating resin having a thermal resistance at a temperature of about 250° C. or higher;
heating the substrate at a second temperature during or after the forming of the protective layer; and
allowing adsorption of dyes in the porous oxide layer.

10. The method according to claim 9, wherein the first temperature is higher than the second temperature.

11. The method according to claim 9, wherein the forming the transparent conductive layer comprises forming the transparent conductive layer to a thickness of about 0.001 to 10 μm.

12. The method according to claim 9, wherein the insulating resin has a thermal resistance at a temperature of about 300° C. or higher.

13. An electrode substrate device for a photoelectric conversion element, comprising:
a substrate;
a collector wire disposed on the substrate;
a transparent conductive layer disposed on the substrate in a region different from a region in which the collector wire is formed;
a porous oxide semiconductor layer disposed on the transparent conductive layer in a region different from a region in which the collector wire is formed;
a protective layer covering the collector wire, the protective layer comprising an insulating resin having a thermal resistance at about 250° C. or higher.

14. The electrode substrate device according to claim 13, wherein
the transparent conductive layer is further disposed on the collector wire, between the collector wire and the protective layer.

15. The electrode substrate device according to claim 13, wherein
the transparent conducive layer is further disposed on the substrate, between the substrate and the collector wire.

16. The electrode substrate device according to claim 13, wherein the insulating resin has a thermal resistance at about 300° C. or higher.

17. The electrode substrate device according to claim 13, wherein the substrate comprises a concave portion in which the collector wire is formed.
